(19) United States
(12) Patent Application Publication
(10) Pub. No.: US 2014/0290994 A1
(43) Pub. Date: Oct. 2, 2014

(54) SURFACE-MODIFIED INORGANIC FILLER, METHOD OF PREPARING THE SAME, BUILDUP FILM COMPOSITION FOR MULTILAYER PRINTED WIRING BOARD, AND THE MULTILAYER PRINTED WIRING BOARD INCLUDING THE SAME

(71) Applicant: SAMSUNG ELECTRO-MECHANICS CO., LTD., Suwon (KR)

(72) Inventors: Ki Seok Kim, Suwon (KR); Ji Hye Shim, Suwon (KR); Hwa Young Lee, Suwon (KR); Joon Ho Bae, Suwon (KR)

(73) Assignee: SAMSUNG ELECTRO-MECHANICS CO., LTD., Suwon (KR)

(21) Appl. No.: 13/963,807

(22) Filed: Aug. 9, 2013

(30) Foreign Application Priority Data
Mar. 26, 2013 (KR) 10-2013-0032213

(51) Int. Cl. C09C 1/30; H05K 1/03; H05K 1/11; C08K 9/06

(52) U.S. Cl. CPC C09C 1/3081; C08K 9/06; H05K 1/0306; H05K 1/119
USPC 174/258; 549/215; 523/456

(57) ABSTRACT

Disclosed herein is a method of preparing a surface-modified inorganic filler, comprising the steps of: drying an inorganic filler; treating the inorganic filler with fluorine-containing gas to bond fluorine (F) to a part of the surface of the inorganic filler; and bonding a functional group-bonded silane coupling agent to another part of the surface of the inorganic filler, this other part of the surface thereof being not bonded with fluorine.

### CROSS REFERENCE TO RELATED APPLICATION

This application claims the benefit of Korean Patent Application No. 10-2013-0032213, filed Mar. 26, 2013, entitled “Surface-modified inorganic filler, method of preparing the same, buildup film composition for multilayer printed wiring board, and the multilayer printed wiring board including the same,” which is hereby incorporated by reference in its entirety into this application.

### BACKGROUND OF THE INVENTION

1. Technical Field

The present invention relates to a surface-modified inorganic filler, a method of preparing the surface-modified inorganic filler, a buildup film composition for a multilayer printed wiring board, and a multilayer printed wiring board including the composition.

2. Description of the Related Art

Recently, as electronic appliances have become small and highly-functional, buildup layers, serving as insulation layers of multilayer printed wiring boards, are typically multilayered. Therefore, the miniaturization and high-integration of wiring is required, and insulation materials having a low dielectric tangent are required.

In order to solve the above problems, various studies have recently been conducted. For example, general research has been conducted into synthesis of an epoxy resin having a low dielectric loss factor, and into a resin composition including an epoxy resin having a low dielectric loss factor, a curing agent and an inorganic filler.

Silica has been generally used as an inorganic filler included in a buildup film. The increase in the amount of silica in a buildup film has a great influence on the decrease in the dielectric loss factor of the buildup film. Therefore, in order to obtain a low thermal expansion coefficient (CTE) of 30 ppm/° C. or less and a low dielectric loss factor (DF) of 0.1 or less, it is required that silica is added in a high content of 60 wt % or more.

Further, in order to allow an inorganic filler having a diameter of several nanometers to several micrometers to effectively exhibit desired physical properties in an epoxy resin composition, it is required that the inorganic filler has excellent dispersibility.

Therefore, in order to assure high dispersibility when silica is added to an epoxy resin composition, generally, a small amount of a silane coupling agent is added to the epoxy resin composition, or silica surface-modified with a silane coupling agent is used. Silica surface-treated with various silane coupling agents has already been commodified and sold on the market.

Meanwhile, when an inorganic filler is added in a high content in order to obtain a low dielectric loss factor, there is a problem in that the workability and mechanical properties of an insulation film are deteriorated. Therefore, it is required to reduce the added amount of an inorganic filler occupying the highest proportion of a buildup film composition by the high-functionalization of the inorganic filler, and it is required to develop a novel surface treatment technology instead of conventional surface treatment technologies using a silane coupling agent in order to prepare a highly functional inorganic filler.

### SUMMARY OF THE INVENTION

Thus, the present inventors found that the above-mentioned problems can be solved by surface-modifying an inorganic filler included in a buildup film composition with a functional group-bonded silane coupling agent and fluorine. Based on this finding, the present invention was completed.

Accordingly, the present invention intends to provide a method of preparing an inorganic filler surface-bonded with a functional group-bonded silane coupling agent and fluorine.

Further, the present invention intends to provide an inorganic filler which is surface-bonded with a functional group-bonded silane coupling agent and fluorine.

Further, the present invention intends to provide a buildup film composition for a multilayer printed wiring board, which includes an inorganic filler surface-bonded with a functional group-bonded silane coupling agent and fluorine.

Further, the present invention intends to provide a multilayer printed wiring board including a buildup film composition containing an inorganic filler surface-bonded with a functional group-bonded silane coupling agent and fluorine.

A first aspect of the present invention provides a method of preparing a surface-modified inorganic filler, including: drying an inorganic filler; treating the inorganic filler with fluorine-containing gas to bond fluorine (F) to a part of the surface of the inorganic filler; and bonding a functional group-bonded silane coupling agent to another part of the surface of the inorganic filler, this other part of the surface thereof being not bonded with fluorine.

In the method, the fluorine and the silane coupling agent may be bonded to the surface of the inorganic filler at a molar ratio of 1:0.1˜0.3.

In the method, the inorganic filler may be selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

In the method, the inorganic filler may be silica.

In the method, the drying of the inorganic filler may be performed at 80 to 120° C. for 0.5 to 2 hours.

In the method, the fluorine-containing gas may be selected from the group consisting of fluorine (F₂), nitrogen trifluoride (NF₃), carbon tetrafluoride (CF₄), carbon trifluoride (CHF₃), tricarbon octafluoride (C₃F₈), tetracarbon octafluoride (C₄F₈), and mixtures thereof.

In the method, the bonding of the fluorine may be performed at a pressure of 0.01 to 0.3 bars.

In the method, the bonding of the fluorine may be performed by directly contacting the inorganic filler with the fluorine-containing gas for 30 seconds to 90 minutes.

In the method, the bonding of the fluorine may be performed by stirring the inorganic filler and the fluorine-containing gas at a rotation speed of 5 to 100 rpm.

In the method, the functional group may be selected from the group consisting of an epoxide group, an amine group, and an alkyl group.

A second aspect of the present invention provides a surface-modified inorganic filler, including: at least one fluorine (F); at least one silane coupling agent, an end of which is bonded with a functional group selected from the group consisting of an epoxide group, an amine group and an alkyl group; and an inorganic filler, wherein the fluorine and the silane coupling agent are bonded to the surface of the inorganic filler, and the functional group of the silane coupling agent is not bonded with the inorganic filler.

In the surface-modified inorganic filler, the fluorine and the silane coupling agent may be bonded to the surface of the inorganic filler at a molar ratio of 1:0.1˜0.3.

In the surface-modified inorganic filler, the inorganic filler may be selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

In the surface-modified inorganic filler, the inorganic filler may be silica.

A third aspect of the present invention provides a buildup film composition for a multilayer printed wiring board, including: the surface-modified inorganic filler; an epoxy resin; and a curing agent.

In the buildup film composition, the epoxy resin may be at least one selected from the group consisting of a naphthalene-based epoxy resin, a bisphenol A type epoxy resin, a phenol novolac epoxy resin, a cresol novolac epoxy resin, a rubber-modified epoxy resin, and a phosphorous-based epoxy resin.

In the buildup film composition, the curing agent may be at least one selected from the group consisting of an active ester curing agent, an amide-based curing agent, a polyamine-based curing agent, an acid anhydride curing agent, a phenol novolac type curing agent, a polymercaptan curing agent, a tertiary amine curing agent, and an imidazole curing agent.

A fourth aspect of the present invention provides a multilayer printed wiring board, including the buildup film composition.

### BRIEF DESCRIPTION OF THE DRAWINGS

The above and other objects, features and advantages of the present invention will be more clearly understood from the following detailed description taken in conjunction with the accompanying drawing, in which:

FIG. 1 is a sectional view showing a general multilayer printed wiring board, to which a buildup film composition containing surface-modified silica according to the present invention can be applied.

### REFERENCE NUMERALS

100: multilayer printed wiring board
110: insulator
120: electronic component
130: buildup layer
131: insulation layer (buildup film or PCC)
132: circuit layer
140: capacitor
150: resistor
160: solder resist
170: external connector
180: pad

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

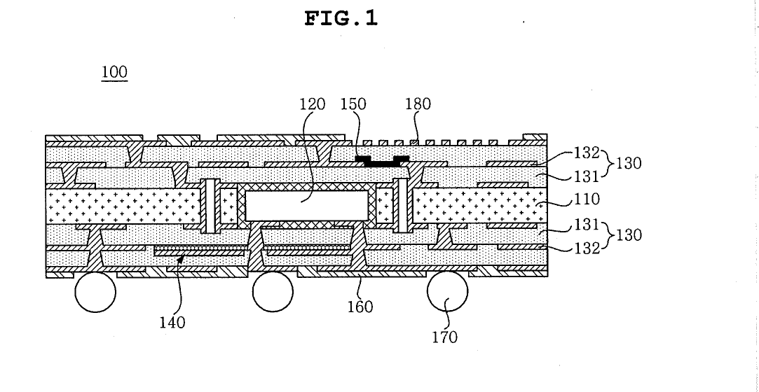

Referring to FIG. 1, a buildup film is used to form an insulation layer of a multilayer printed wiring board. Currently, since such multilayer printed wiring boards are becoming increasingly thin and small, various inorganic fillers having a low thermal expansion coefficient and high heat transfer efficiency are added to a buildup film composition in order to prevent the warpage of the multilayer printed wiring boards and improve the heat radiation characteristics thereof. Meanwhile, currently, the amount of an inorganic filler added is gradually increasing. As described above, the present invention intends to provide a highly functional inorganic filler which can reduce the dielectric low factor of an insulation layer by modifying the surface thereof and which can be effectively dispersed in an epoxy resin. Hereinafter, a method of preparing an inorganic filler according to the present invention, and an inorganic filler prepared by this method will be described in detail.

The method of preparing a surface-modified inorganic filler according to the present invention includes: drying an inorganic filler; treating the inorganic filler with fluorine-containing gas to bond fluorine (F) to a part of the surface of the inorganic filler; and bonding a functional group-bonded silane coupling agent to another part of the surface of the inorganic filler, this other part of the surface thereof being not bonded with fluorine. According to the method of the present invention, since the surface of the dried inorganic filler is treated with fluorine-containing gas by a gas-phase treatment process, unreacted products and impurities scarcely remain after the reaction, and thus a surface-modified inorganic filler can be efficiently prepared in an environment-friendly manner. Further, according to the method of the present invention, since fluorine and a silane coupling agent are simultaneously bonded to the surface of silica at a predetermined ratio, highly functional silica can be prepared. Hereinafter, the method of preparing a surface-modified inorganic filler will be described stepwisely.

First, an inorganic filler to be surface-modified is thermally dried for about 12 hours using an oven. In this case, the inorganic filler may be selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate. Particularly, in the present invention, it is preferred that silica be used as the inorganic filler, but the inorganic filler is not limited thereto as long as the object of the present invention can be accomplished. Meanwhile, the drying time of the inorganic filler can be adjusted according to the kind, amount and particle size of the inorganic filler.

The inorganic filler dried in this way is introduced into a gas-phase-treatable chamber, and then fluorine-containing gas is supplied into the chamber. Here, examples of the fluorine-containing gas may include, but are not limited to, fluorine (F₂), nitrogen trifluoride (NF₃), carbon tetrafluoride (CF₄), carbon trifluoride (CHF₃), tricarbon octafluoride (C₃F₈), tetracarbon octafluoride (C₄F₈), and mixtures thereof. The fluorine-containing gas may be used without limitation as long as it can provide a fluorine to the surface of the inorganic filler.

The drying of the inorganic filler may be performed at 80 to 120° C. for 0.5 to 2 hours. When the drying temperature is lower than 80° C., there is a problem in that the inorganic filler is not sufficiently dried to such a degree that it is suitable for gas-phase treatment, and when the drying temperature is higher than 120° C., there is a problem in that the surface of silica is excessively dried, and thus the physical properties of silica are deteriorated. Further, when the drying time is less than 0.5 hours, there also is a problem in that the inorganic filler is not sufficiently dried to such a degree that it is suitable for gas-phase treatment, and when the drying time is more than 2 hours, there also is a problem in that the surface of silica is excessively dried, and thus the physical properties of silica are deteriorated.

The gas-phase treatment of the inorganic filler in the chamber may be performed at a pressure of 0.01 to 0.3 bars. When a pressure of less than 0.01 bar is applied, there is a problem in that a fluorine is not easily provided to the surface of the inorganic filler, and when a pressure of more than 0.3 bar is applied, there is a problem in that reactivity is deteriorated.

Further, the reaction of the inorganic filler with the fluorine-containing gas in the chamber may be performed by stirring the inorganic filler and the fluorine-containing gas at a rotation speed of 5 to 100 rpm. When the stirring speed is less than 5 rpm, there is a problem in that the inorganic filler and the fluorine-containing gas are not uniformly mixed, and when the stirring speed is more than 100 rpm, there is a problem in that reactivity is deteriorated.

Particularly, in order to provide a fluorine to the surface of the inorganic filler by gas-phase treatment, the inorganic gas and the fluorine-containing gas must make direct contact with each other for 30 seconds to 90 minutes. When the contact time is less than 30 seconds, there is a problem in that it is difficult to efficiently provide the fluorine group to the surface of the inorganic filler, and when the contact time is more than 90 minutes, there is a problem in that a large number of fluorine groups is provided to the surface of the inorganic filler, and thus the following silane coupling agent cannot be efficiently provided to the surface of the inorganic filler.

Through the gas-phase treatment process, an inorganic filler, a part of the surface of which is provided with a fluorine, can be obtained. This gas-phase treatment process is advantageous in that it is environment-friendly, unreacted products and impurities are produced in small amounts, and reaction pressure and reaction time can be adjusted, and thus it is easy to control the amount of introduced fluorine. However, a conventional liquid-phase treatment process can also be used in order to provide a fluorine to the surface of an inorganic filler.

Subsequently, a silane coupling agent is provided to a part of the surface of the inorganic filler modified with fluorine by the gas-phase treatment process.

One end of the silane coupling agent used in the present invention is chemically bonded with a functional group having excellent compatability with an epoxy resin. It is preferred that an epoxide group, an amine group or an alkyl group be used as the functional group. However, the functional group may be used without limitation as long as it has excellent compatibility with an epoxy resin.

The inorganic filler surface-modified with such a functional group exhibits excellent dispersibility because the compatibility thereof with an epoxy resin in the buildup film composition is excellent. As a result, it is possible to prepare a buildup film composition having a low dielectric loss factor without deterioration in the mechanical properties of the buildup film composition attributable to the aggregation of the inorganic filler.

The process of bonding the silane coupling agent provided with the functional group to the surface of the inorganic filler may be performed by a liquid-phase treatment process. Further, such a silane coupling agent may also be provided to the surface of the inorganic filler by a commonly-known method.

Meanwhile, since the reactivity of a silane coupling agent with an inorganic filler including silica is very high, when the silane coupling agent is previously provided to the surface of the inorganic filler before the inorganic filler is gas-phase-treated with a fluorine-containing gas, most of the surface of the inorganic filler is bonded with the silane coupling agent, and thus it is difficult to secure the above-mentioned surface of the inorganic filler to be provided with a fluorine. Therefore, it is preferred that the silane coupling agent be provided to the surface of the inorganic filler after the gas-phase treatment of the inorganic filler with the fluorine group.

It is preferred that the fluorine and the silane coupling agent be bonded to the surface of the inorganic filler at a molar ratio of 1:0.1˜0.3. When the molar ratio of the silane coupling agent to the fluorine is less than 0.1, there is a problem in that the dispersibility of the surface-modified inorganic filler in an epoxy resin deteriorates, and when the molar ratio of the silane coupling agent to the fluorine is more than 0.3, there is a problem in that the dielectric loss factor of an insulation resin composition increases.

The surface-modified inorganic filler according to the present invention includes: at least one fluorine (F); at least one silane coupling agent, an end of which is bonded with a functional group selected from the group consisting of an epoxide group, an amine group and an alkyl group; and an inorganic filler, wherein the fluorine and the silane coupling agent are bonded to the surface of the inorganic filler, and the functional group of the silane coupling agent is not bonded with the inorganic filler.

The fluorine (F) bonded to the surface of the inorganic filler is advantageous in that it can be easily surface-treated compared to other halogen elements, and in that it has low surface free energy. In particular, since a C—F bond has the lowest electronic polarizability, fluorine-containing materials have low dielectric loss factor characteristics. For example, Teflon (polytetrafluoroethylene) containing fluorine is characterized in that it has very low surface tension, and does not have affinity for both hydrophilic water and hydrophobic oil.

Meanwhile, the fluorine and the silane coupling agent may be bonded to the surface of the inorganic filler at a molar ratio of 1:0.1˜0.3. The inorganic filler may be selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate, but is not limited thereto. Particularly, silica has a low thermal expansion coefficient, a relatively excellent heat transfer rate, a low dielectric loss factor and a low price. Therefore, it is preferred that silica be used as the inorganic filler of the present invention.

As such, the surface-modified inorganic filler according to the present invention is advantageous in that, since it has low surface tension, the affinity of this inorganic filler for water is reduced, and thus the moisture content of an epoxy resin composition is lowered, thereby decreasing the dielectric loss factor of the epoxy resin composition.

Particularly, the surface-modified inorganic filler according to the present invention is advantageous in that it has low dielectric loss characteristics because it is provided with a fluorine, and it exhibits excellent dispersibility because it is provided with a silane coupling agent bonded with a functional group having excellent compatibility with an epoxy resin, thus greatly reducing a dielectric low factor by the addition of the inorganic filler in an amount of 70 wt % or less.

The buildup film composition for a multilayer printed wiring board according to the present invention includes: the surface-modified inorganic filler; an epoxy resin; and a curing agent.

The epoxy resin may be at least one selected from the group consisting of a naphthalene-based epoxy resin, a bisphenol A type epoxy resin, a phenol novolac epoxy resin, a cresol novolac epoxy resin, a rubber-modified epoxy resin, and a phosphorous-based epoxy resin, but is not limited thereto.

The curing agent may be at least one selected from the group consisting of an active ester curing agent, an amide-based curing agent, a polyamine-based curing agent, an acid anhydride curing agent, a phenol novolac type curing agent, a polymercaptan curing agent, a tertiary amine curing agent, and an imidazole curing agent, but is not limited thereto.

The multilayer printed wiring board according to the present invention includes the buildup film composition.

Hereinafter, the present invention will be described in more detail with reference to the following Examples. However, these Examples are set forth to illustrate the present invention, and the scope of the present invention is not limited thereto.

### Example 1

Silica was dried at 100° C. for about 12 hours using an oven. The dried silica was put into a reaction chamber, fluorine-containing gas (F₂) was introduced into the reaction chamber, and then stirring was carried out under a pressure of 0.1 bar for 10 minutes at a rotation speed of 50 rpm. Through such a primary gas-phase treatment process, silica having a fluorine on the surface thereof was recovered. Thereafter, a secondary liquid-phase treatment process for reacting a silane coupling agent having an epoxy group at one end thereof with the recovered silica was conducted to prepare surface-modified silica. The surface-modified silica (70 wt %) prepared by the secondary liquid-phase treatment process was formed into a slurry using a solvent MEK (methyl ethyl ketone), and the slurry was mixed with an epoxy resin by stirring. Then, this slurry was cured using triazine novolac to obtain a polymer composite sample. In Example 1, the ratio of the fluorine and silane coupling agent provided on the surface of silica was adjusted to 1:0.3.

### Example 2

A polymer composite sample was obtained in the same manner as in Example 1, except that the ratio of the fluorine and silane coupling agent provided on the surface of silica was adjusted to 1:0.1.

### Comparative Example 1

A polymer composite sample was obtained in the same manner as in Example 1, except that silica, not surface-treated, was used.

### Comparative Example 2

A polymer composite sample was obtained in the same manner as in Example 1, except that silica provided with only fluorine by gas-phase treatment was used.

### Comparative Example 3

A polymer composite sample was obtained in the same manner as in Example 1, except that silica provided with only a silane coupling having an epoxy resin was used.

The dielectric loss factors of the buildup films obtained using the compositions of Examples 1 and 2 and Comparative Examples 1 to 3 and the relative dispersibility values of silica in a resin of the compositions thereof were measured, and the results thereof are shown in Table 1 below.

TABLE 1

| | Dielectric loss | Silica dispersability |
|---|---|---|
| | factor (Df) | (relative value) |
| Example 1 | 0.0070 | 0.7 |
| Example 2 | 0.0066 | 0.8 |
| Comparative Example 1 | 0.0086 | 0.4 |
| Comparative Example 2 | 0.0074 | 0.6 |
| Comparative Example 3 | 0.0080 | 1.0 |

As shown in Table 1 above, it can be ascertained that, in the case of Comparative Example 1 in which silica, not surface-modified, was used, the dielectric loss factor of the buildup film is comparatively high, and the dispersibility of an inorganic filler (silica) is very low. Further, it can be ascertained that, in the case of Comparative Example 2 in which silica provided on the surface thereof with only a fluorine was used, the dielectric loss factor of the buildup film is low, but the dispersibility of silica is comparatively low. Further, it can be ascertained that, in the case of Comparative Example 3 in which silica provided on the surface thereof with only a silane coupling agent having an epoxy group was used, the dispersibility of silica is comparatively high, but the dielectric loss factor of the buildup film is high.

However, it can be ascertained that, in the cases of Examples 1 and 2, in each of which silica provided on the surface thereof with both a fluorine and a silane coupling agent having an epoxy group was used, low dielectric loss characteristics as well as high silica dispersibility was accomplished.

As described above, according to the present invention, since a functional group-bonded silane coupling agent and fluorine are bonded to the surface of an inorganic filler, the dielectric loss factor of a buildup film composition used in an insulation layer of a multilayer printed wiring board can be lowered, and the dispersability of an inorganic filler in epoxy resin can be improved due to the compatibility of the inorganic filler with the epoxy resin. Further, according to the present invention, since the surface of an inorganic filler is gas phase-treated using fluorine-containing gas, an inorganic filler surface-modified with fluorine can be prepared in a simple and economical manner, and the amount of fluorine applied to the surface of the inorganic filler can be easily controlled by adjusting reaction pressure and time.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A method of preparing a surface-modified inorganic filler, comprising:
drying an inorganic filler;
treating the inorganic filler with fluorine-containing gas to bond fluorine (F) to a part of the surface of the inorganic filler; and
bonding a functional group-bonded silane coupling agent to another part of the surface of the inorganic filler, this other part of the surface thereof being not bonded with fluorine.

2. The method of claim 1, wherein the fluorine and the silane coupling agent are bonded to the surface of the inorganic filler at a molar ratio of 1:0.1˜0.3.

3. The method of claim 1, wherein the inorganic filler is selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

4. The method of claim 1, wherein the inorganic filler is silica.

5. The method of claim 1, wherein the drying of the inorganic filler is performed at 80 to 120° C. for 0.5 to 2 hours.

6. The method of claim 1, wherein the fluorine-containing gas is selected from the group consisting of fluorine (F₂), nitrogen trifluoride (NF₃), carbon tetrafluoride (CF₄), carbon trifluoride (CHF₃), tricarbon octafluoride (C₃F₈), tetracarbon octafluoride (C₄F₈), and mixtures thereof.

7. The method of claim 1, wherein the bonding of the fluorine is performed at a pressure of 0.01 to 0.3 bars.

8. The method of claim 1, wherein the bonding of the fluorine is performed by directly contacting the inorganic filler with the fluorine-containing gas for 30 seconds to 90 minutes.

9. The method of claim 1, wherein the bonding of the fluorine is performed by stirring the inorganic filler and the fluorine-containing gas at a rotation speed of 5 to 100 rpm.

10. The method of claim 1, wherein the functional group is selected from the group consisting of an epoxide group, an amine group, and an alkyl group.

11. A surface-modified inorganic filler, comprising:
at least one fluorine (F);
at least one silane coupling agent, an end of which is bonded with a functional group selected from the group consisting of an epoxide group, an amine group and an alkyl group; and
an inorganic filler,
wherein the fluorine and the silane coupling agent are bonded to the surface of the inorganic filler, and the functional group of the silane coupling agent is not bonded with the inorganic filler.

12. The surface-modified inorganic filler of claim 11, wherein the fluorine and the silane coupling agent are bonded to the surface of the inorganic filler at a molar ratio of 1:0.1˜0.3.

13. The surface-modified inorganic filler of claim 11, wherein the inorganic filler is selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

14. The surface-modified inorganic filler of claim 11, wherein the inorganic filler is silica.

15. A buildup film composition for a multilayer printed wiring board, comprising:
the surface-modified inorganic filler of claim 11;
an epoxy resin; and
a curing agent.

16. The buildup film composition of claim 15, wherein the epoxy resin is at least one selected from the group consisting of a naphthalene-based epoxy resin, a bisphenol A type epoxy resin, a phenol novolac epoxy resin, a cresol novolac epoxy resin, a rubber-modified epoxy resin, and a phosphorous-based epoxy resin.

17. The buildup film composition of claim 15, wherein the curing agent is at least one selected from the group consisting of an active ester curing agent, an amide-based curing agent, a polyamine-based curing agent, an acid anhydride curing agent, a phenol novolac type curing agent, a polymercaptan curing agent, a tertiary amine curing agent, and an imidazole curing agent.

18. A multilayer printed wiring board, comprising the buildup film composition of any one of claim 15.
